(19) United States
(12) Patent Application Publication
(10) Pub. No.: US 2026/0282561 A1
(43) Pub. Date: Sep. 17, 2026

(54) INTEGRATED CIRCUIT WITH ELECTROSTATIC DISCHARGE STRUCTURE

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: CunCun CHEN, Shanghai City (CN); Huan-Neng CHEN, Taichung City (TW); Shao-Yu LI, Hsinchu City (TW); Tzu-Heng CHANG, New Taipei City (TW); Yi-Feng CHANG, New Taipei City (TW); Di FAN, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/095,140

(22) Filed: Mar. 31, 2025

(30) Foreign Application Priority Data
Mar. 14, 2025 (CN) 202520454780.0

(51) Int. Cl. H10D 89/60; H01L 23/528

(52) U.S. Cl. CPC H10D 89/811; H10W 20/427; H10W 20/43

(57) ABSTRACT

An integrated circuit is provided and includes a header circuit coupled to a first voltage terminal providing a first supply voltage and configured to provide a second supply voltage at a second voltage terminal; a receiver/transmitter circuit coupled between the second voltage terminal and a third voltage terminal providing a third supply voltage smaller than the second supply voltage; and an electrostatic discharge (ESD) protection circuit coupled to a pad and the receiver/transmitter circuit, and further coupled between the first voltage terminal and the third voltage terminal.

### CROSS REFERENCE

The present application claims priority to China Application Serial Number 202520454780.0 filed on Mar. 14, 2025, which is herein incorporated by reference in its entirety.

### BACKGROUND

The recent trend in miniaturising integrated circuits (ICs) has resulted in smaller, more power-efficient devices that can perform at higher speeds. The miniaturisation process has also introduced stricter design and manufacturing specifications, as well as reliability challenges. In particular, there are concerns about the performance and area efficiency of input and output devices in ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of an IC device 100, in accordance with some embodiments.

FIG. 2 is a schematic diagram of part of an input/output circuit corresponding to FIG. 1, in accordance with some embodiments.

FIG. 3 is a schematic diagram in a layout view of part of an integrated circuit, in accordance with some embodiments.

FIG. 4A is a schematic diagram in a layout view of part of an integrated circuit, in accordance with some embodiments.

FIG. 4B depicts a cross-section diagram of the integrated circuit of FIG. 4A, along line AA′, in accordance with some embodiments.

FIG. 5 is a schematic diagram in a layout view of part of an integrated circuit, in accordance with some embodiments.

FIG. 6A is a schematic diagram in a layout view of part of an integrated circuit, in accordance with some embodiments.

FIG. 6B depicts a cross-section diagram of the integrated circuit of FIG. 6A, along line BB′, in accordance with some embodiments.

FIG. 6C depicts a cross-section diagram of the integrated circuit of FIG. 6A, along line CC′, in accordance with some embodiments.

FIG. 7 is a schematic diagram in a layout view of part of an integrated circuit, in accordance with some embodiments.

FIG. 8 is a schematic diagram in a layout view of part of the integrated circuit of FIG. 7, in accordance with some embodiments.

FIGA. 9A and 9B are schematic diagrams of antenna effect protection circuits corresponding to FIG. 1 and FIG. 7, in accordance with some embodiments.

FIG. 10 is a flow chart of a method 1000 of manufacturing an integrated circuit, in accordance with some embodiments.

FIG. 11 is a block diagram of a system for designing the integrated circuit layout design, in accordance with some embodiments of the present disclosure.

FIG. 12 is a block diagram of an integrated circuit manufacturing system, and an integrated circuit manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

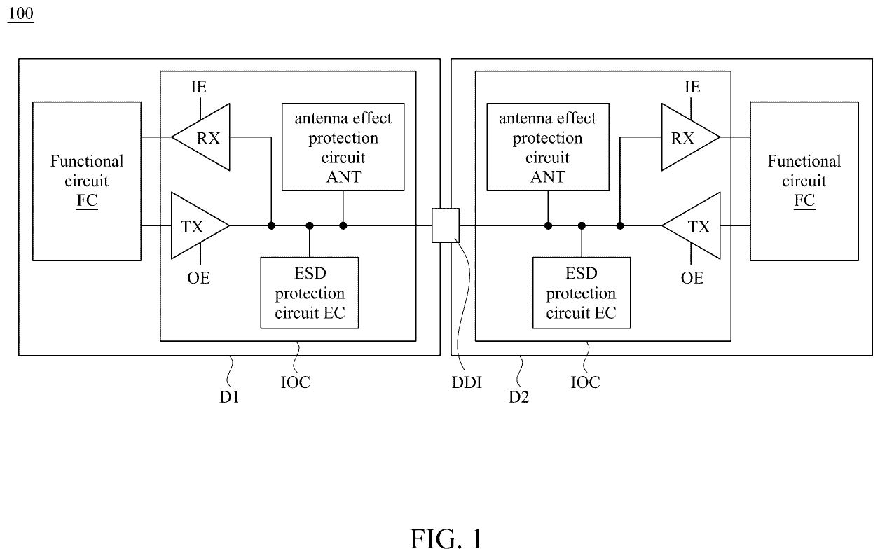

Reference is now made to FIG. 1. FIG. 1 is a schematic block diagram of an IC device 100, in accordance with some embodiments. The IC device 100 comprises a first die D1 and a second die D2 electrically and/or physically coupled to each other. In some embodiments, the first die D1 and the second die D2 are stacked over each other, and are physically bonded and electrically coupled to each other in a 3D IC. In some embodiments, the first die D1 and the second die D2 are arranged side-by-side on and physically bonded to a further substrate or die (not shown), and are electrically coupled to each other through the further substrate or die. In some embodiments, the IC device 100 comprises more than two dies electrically and/or physically coupled to each other. In some embodiments, the IC device 100 has one die, e.g., the first die D1, whereas the other die, e.g., the second die D2, is omitted. In the example configuration in FIG. 1, the second die D2 is configured similarly to the first die D1. The first die D1 is described in detail herein, and a detailed description of the second die D2 is omitted.

The first die D1 comprises one or more functional circuits and one or more input/output (I/O) circuits electrically coupled to the one or more functional circuits. In FIG. 1, a representative functional circuit FC and a representative I/O circuit IOC of the first die D1 are illustrated.

The functional circuit FC is configured to perform an intended function, e.g., data processing or data storage, of the IC device 100. Examples of one or more circuits, logics, or cells included in the functional circuit FC include, but are not limited to, AND, OR, NAND, NOR, XOR, INV, OR-AND-Invert (OAI), MUX, Flip-flop, BUFF, Latch, delay, clock, memory, or the like. The circuits, logics, or cells included in the functional circuit FC include functional transistors or core transistors which are to be protected from the antenna effect during the manufacture of the IC device 100. Examples of transistors in the functional circuit FC, as well as in the other circuits described herein, include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

The I/O circuit IOC is electrically coupled to the functional circuit FC, and is configured as an interface between the functional circuit FC on the first die D1 and external circuitry outside the first die D1. In the example configuration in FIG. 1, the I/O circuit IOC comprises a receiver RX (also referred to as “input circuit”), a transmitter TX (also referred to as “output circuit”), an electrostatic discharge (ESD) protection circuit and an antenna effect protection circuit ANT, all of which are electrically coupled to a pad or pin I which is an I/O pin. In some embodiments, the first die D1 comprises a further antenna effect protection circuit outside of the I/O circuit IOC, which is outside the I/O circuit IOC and also electrically coupled to the pin I.

The receiver RX is configured to send a signal on the pin I to the functional circuit FC. The receiver RX is configured to receive an input enable signal IE. The receiver RX is enabled to send the signal on the pin I to the functional circuit FC in response to a logic state of the input enable signal IE, and is disabled from sending the signal on the pin I to the functional circuit FC in response to a different logic state of the input enable signal IE. The transmitter TX is configured to send a signal output by the functional circuit FC to the pin I. The transmitter TX is configured to receive an output enable signal OE. The transmitter TX is enabled to send the signal output by the functional circuit FC to the pin I in response to a logic state of the output enable signal OE, and is disabled from sending the signal output by the functional circuit FC to the pin I in response to a different logic state of the output enable signal OE. Examples of the signal(s) input from or output to the pin I include, but are not limited to, data, power, clock, control, or the like. Examples of one or more circuits in at least one of the receiver RX or transmitter TX include, but are not limited to, a buffer, a latch, a level shifter, or the like.

The ESD protection circuit EC is configured to protect the other circuits, including the functional circuit FC, that are electrically coupled to the pin I from ESD events occurring on the pin I during operation or handling of the first die D1 or IC device 100. In some embodiments, transistors in the ESD protection circuit EC are larger than and/or have a different configuration from the functional transistors or core transistors of the functional circuit FC to be able to sustain and handle high voltages and/or current of ESD events.

The antenna effect protection circuit ANT is internal to the I/O circuit IOC. The antenna effect protection circuit ANT is configured to protect transistors of the functional circuit FC from being damaged due to the antenna effect during the manufacture of the first die D1 or IC device 100. For example, transistors of the functional circuit FC, which have gate electrodes electrically coupled by one or more conductive patterns and/or vias to the pin I, are protectable by the antenna effect protection circuit ANT from the antenna effect. In some embodiments, transistors in the antenna effect protection circuit ANT have the same size and/or configuration as transistors in the functional circuit FC. In at least one embodiment, transistors in the antenna effect protection circuit ANT are identical to transistors in the functional circuit FC. The transistors in the antenna effect protection circuit ANT are smaller than and/or have a different configuration from the transistors in the ESD protection circuit EC.

In at least one embodiment, a layout diagram of the I/O circuit IOC, including the antenna effect protection circuit ANT, is stored as a cell or module in a standard cell library (also referred to as “cell library”). At a design stage, an APR tool places the antenna effect protection circuit ANT, as part of the I/O circuit IOC, into a layout diagram of the first die D1. The APR tool performs no or little further routing for the antenna effect protection circuit ANT. The APR tool then performs routing individually for the placed one or more antenna cells. In some embodiments, the antenna effect protection circuit ANT includes one or more antenna cells individually placed and/or routed by an APR tool. In some embodiments, one or more antenna cells, or antenna effect protection circuits, are included in the functional circuit FC to provide antenna effect protection for transistors which are too far from and/or not electrically coupled to the pin I.

The first die D1 is electrically coupled to the second die D2 at one or more die-to-die interconnects. In FIG. 1, a representative die-to-die interconnect DDI is illustrated, and is electrically coupled to the pin I of the first die D1 and to a corresponding pin I of the second die D2. As a result, the pin I of the first die D1 is electrically coupled to the corresponding pin I of the second die D2 through the die-to-die interconnect DDI. In some embodiments, the die-to-die interconnect DDI is a pad in one or more dies of the IC device 100.

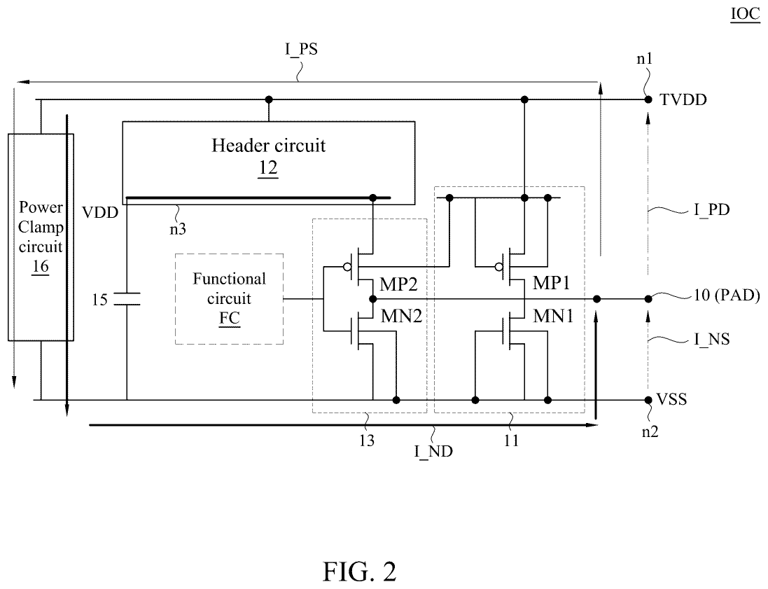

Reference is now made to FIG. 2. FIG. 2 is a schematic diagram of part of the input/output circuit IOC corresponding to FIG. 1, in accordance with some embodiments.

For illustration, the I/O circuit IOC includes an electrostatic discharge (ESD) protection circuit 11, a header circuit 12, a receiver/transmitter circuit 13 coupled to the functional circuit FC, a capacitor unit 15, and a power clamp circuit 16. In some embodiments, the ESD protection circuit 11 is configured with respect to, for example, the ESD protection circuit EC of FIG. 1. The receiver/transmitter circuit 13 is configured with respect to, for example, the receiver RX and the transmitter TX of FIG. 1.

As shown in FIG. 2, the ESD protection circuit 11 and the power clamp circuit 16 are coupled in parallel between a voltage terminal n1 and a voltage terminal n2. The header circuit 12 is coupled to the voltage terminal n1 and another voltage terminal n3. The receiver/transmitter circuit 13 and the capacitor unit 15 are coupled in parallel between the voltage terminal n2 and the voltage terminal n3. Alternatively stated, in some embodiments, the capacitor unit 15 is disconnected from terminals of the transistor MP1.

In some embodiments, the voltage terminal n1 is configured to receive a power supply voltage True VDD (herein “TVDD”). In some embodiments, the supply voltage TVDD is generated by an external voltage supply outside the IC device 100 of FIG. 1. In some embodiments, the supply voltage TVDD is generated by an internal voltage supply included in the IC device 100.

The voltage terminal n2 is configured to be coupled to a supply voltage VSS. In some embodiments, the supply voltage is a ground or has a voltage level smaller than that of the supply voltage TVDD.

In some embodiments, the header circuit 12 is configured to receive the supply voltage TVDD from the voltage terminal n1 and further to provide a supply voltage VDD to the voltage terminal n3. In some embodiments, the supply voltage VDD is referred to as a virtual voltage supply. In some embodiments, the supply voltage TVDD is different from the supply voltage VDD. For example, the supply voltage is greater than the supply voltage VDD by 0.3-0.5 Volt. In some embodiments, the supply voltage TVDD is the same as the supply voltage VDD.

Specifically, the ESD protection circuit 11 includes a P-type transistor MP1 and a N-type transistor MN1. The transistor MP1 has a drain/source terminal coupled to the pad 10 and has a gate terminal and a source/drain terminal that are coupled to the voltage terminal n1. The transistor MN1 has a source/drain terminal coupled to the drain/source terminal of the transistor MP1 and the receiver/transmitter circuit 13 at the pad 10 and has a gate terminal and a drain/drain terminal that are coupled to the voltage terminal n2.

The receiver/transmitter circuit 13 includes a P-type transistor MP2 and a N-type transistor MN2. The transistor MP2 has a source/drain terminal coupled to the voltage terminal n3 and a drain/source terminal coupled to the pad 10. The transistor MN2 has a gate terminal coupled to a gate terminal of the transistor MP2, a source/drain terminal coupled to the voltage terminal n2, and a drain/source terminal coupled to the pad 10 and the ESD protection circuit 11. The gate terminals of the transistors MP2 and MN2 are coupled to the functional circuit FC.

In some embodiments, body terminals of the transistors MP1-MP2 are coupled to the voltage terminal n1 to receive the supply voltage TVDD. Alternatively stated, the body terminal of the transistor MP2 in the receiver/transmitter circuit 13 is coupled to the gate and source/drain terminals of the transistor MP1. Body terminals of the transistors MN1-MN2 are coupled to the voltage terminal n2 to receive the supply voltage VSS.

According to some embodiments, the ESD protection circuit 11 is configured to discharge ESD current induced by charges inserted to the pad 10 during ESD events.

For example, during the ESD Positive-to-VDD (hereinafter referred to as “PD mode”) or positive electrostatic discharged event, the transistor MP1 discharges the positive electrostatic charges inserted at the pad 10 as an ESD current I_PD that flows from the pad 10 to the voltage terminal n1.

In another embodiment, during the ESD Positive-to-VSS (hereinafter referred to as “PS mode”), the transistor MP1 in the ESD protection circuit 11 and the power clamp circuit 16 discharge the positive electrostatic charges inserted at the pad 10 as an ESD current I_PS that flows from the pad 10 to the voltage terminal n2.

In yet another embodiment, during an ESD negative-to-VSS (hereinafter referred to as “NS mode”) or negative electrostatic discharged event, the transistor MN1 of the ESD protection circuit 11 discharges the negative electrostatic charges to the voltage terminal n2 from the pad 10, which are referred to as a positive ESD current I_NS flowing to the pad 10.

In some embodiment, during an ESD negative-to-VDD (hereinafter referred to as “ND mode”) or negative electrostatic discharged event, the transistor MN1 of the ESD protection circuit 11 and the power clamp circuit 16 discharge the negative electrostatic charges to the voltage terminal n1 from the pad 10, which are referred to as a positive ESD current I_ND flowing to the pad 10.

While some die-to-die connection input/output circuit approaches co-optimize components like ESD protection, transmitter, and receiver circuits for electrical performance and electromagnetic compatibility with antenna rules, they often lead to increased area usage. This is primarily due to the inclusion of TAP embeddings and multiple power clamp circuits connected to supply voltage terminals. Specifically, the need for power clamp circuits between VDD and VSS voltage terminals for ESD discharging in PS and ND modes contributes to this area penalty and can increase leakage current.

The configuration of the present application optimizes area and leakage performance by integrating ESD protection directly into the power delivery network. A ground-gated N-type MOS and a P-type MOS, with source/drain and gate terminals connected to the TVDD voltage terminal, provide ESD protection. This eliminates the need for a separate power clamp circuit between VDD and VSS, reducing both die area and leakage current.

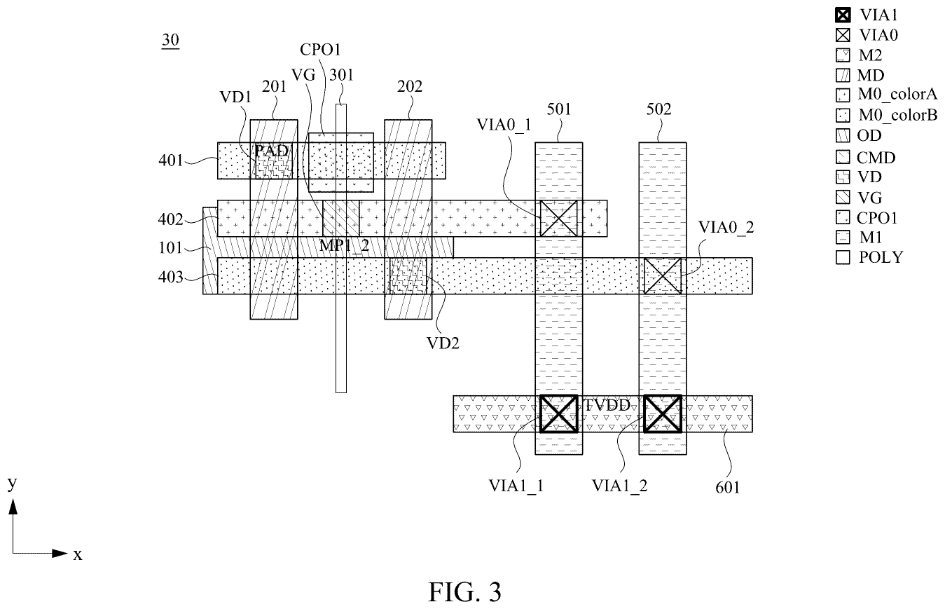

Reference is now made to FIG. 3. FIG. 3 is a schematic diagram in a layout view of part of an integrated circuit 30, in accordance with some embodiments. In some embodiments, the integrated circuit 30 is configured with respect to, for example, the I/O circuit IOC of FIG. 2.

The integrated circuit 30 has a transistor MP1_2 that is configured with respect to, for example, the transistor MP1 of FIG. 2. As illustratively shown in FIG. 3, the transistor MP1 includes an active area (e.g., oxide diffusion, “OD”) 101 extending in x direction, conductive segments (e.g., metal-on-device, “MD”) 201-202 extending in the y direction, and a gate structure (e.g., polysilicon, “poly”) 301 extending in the y direction and interposed between the conductive segments 201-202. The integrated circuit 30 further includes conductive lines (e.g., metal-zero layer, “M0”) 401-403, conductive rails (e.g., metal-one layer, “M1”) 501-502, and a conductive trace 601 (e.g., metal-two layer, “M2”.)

In some embodiments, the conductive segments 201-202 and the gate structure 301 are in a first layer above the active area 101. The conductive lines 401-403 extend in x direction and are disposed in a second layer above the first layer. The conductive lines 401-403 are separated from each other in y direction. The conductive rails 501-502 extend in y direction and are disposed in a third layer above the second layer. The conductive rails 501-502 are separated from each other in x direction. The conductive trace 601 is in a fourth layer above the third layer and extends in x direction. In some embodiments, the gate structure 301 is trimmed by a poly cut layer (also referred to as “CPO” in some embodiments.)

In some embodiments, the gate structure 301 corresponds to the gate terminal of the transistor MP1_2. The conductive segment 201 corresponds to the drain/source terminal of the transistor MP1_2. The conductive segment 202 corresponds to the source/drain terminal of the transistor MP1_2.

The conductive segment 201 is coupled to the conductive line 401 through a via VD1, in which the conductive line 401 is coupled to the pad. The gate structure 301 is coupled to the conductive line 402 through a via VG1. The conductive segment 202 is coupled to the conductive line 403 through a via VD2. The conductive lines 402 and 403 are respectively coupled to the conductive rails 501 and 502 through vias VIA0_1 and VIA0_2. The conductive rails 501 and 502 are coupled to the conductive trace 601 through vias VIA1_1 and VIA1_2 respectively, in which the conductive trace 601 is coupled to the voltage terminal n1 that receives the supply voltage TVDD.

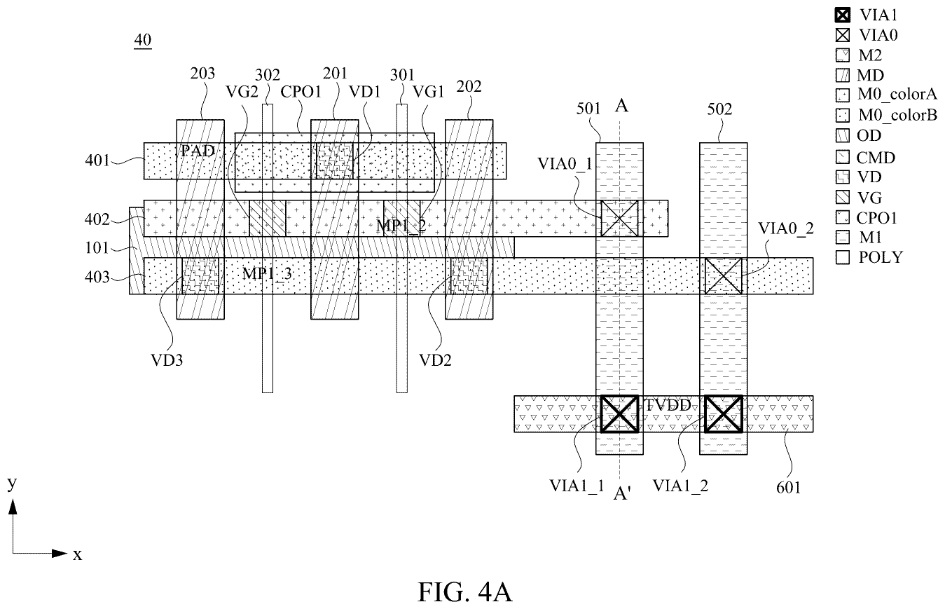

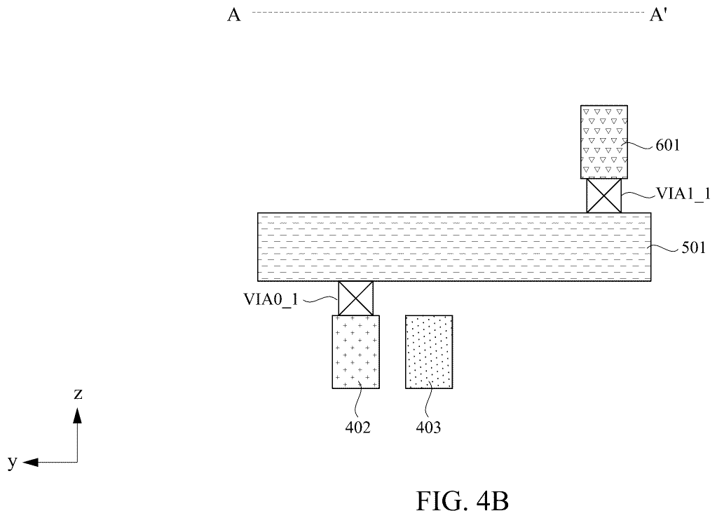

Reference is now made to FIG. 4A. FIG. 4A is a schematic diagram in a layout view of part of an integrated circuit 40, in accordance with some embodiments. With respect to the embodiments of FIGS. 1-3, like elements in FIG. 4A are designated with the same reference numbers for ease of understanding. The specific operations of similar elements, which are already discussed in detail in above paragraphs, are omitted herein for the sake of brevity.

In the embodiments of FIG. 4A, the integrated circuit 40 further includes a P-type transistor MP1_3 coupled in parallel with the transistor MP1_2 to implement the transistor MP1 of FIG. 2. Specifically, the integrated circuit 40 includes a conductive segment 203 and a gate structure 302 that are disposed above the active area 101.

In some embodiments, the conductive segment 203 corresponds to a source/drain terminal of the transistor MP1_3 coupled to the voltage terminal n1 through coupled to a via VD3, the conductive line 403, the conductive rail 502, and the conductive trace 601. The conductive segment 201 further corresponds to the drain/source terminal of the transistor MP1_3.

The gate structure 302 corresponds to the gate terminal of the transistor MP1_3 and is coupled to the conductive line 402 and further coupled to the supply voltage TVDD through the conductive rail 501 and the conductive trace 601.

FIG. 4B depicts a cross-section diagram of the integrated circuit 40 of FIG. 4A, along line AA′, in accordance with some embodiments.

As illustratively shown in FIG. 4B, the conductive line 402 is disposed below the conductive rail 501 and the conductive trace 601, and is electrically coupled to the conductive rail 501 through via VIA0_1. The conductive rail 501 is coupled to the conductive trace 601 through via VIA1_1. Accordingly, in some embodiments, the ESD protection circuit 11 discharges the ESD current (e.g., I_PD and/or I_PS) through the conductive line 402, the conductive rail 501, and the conductive trace 601.

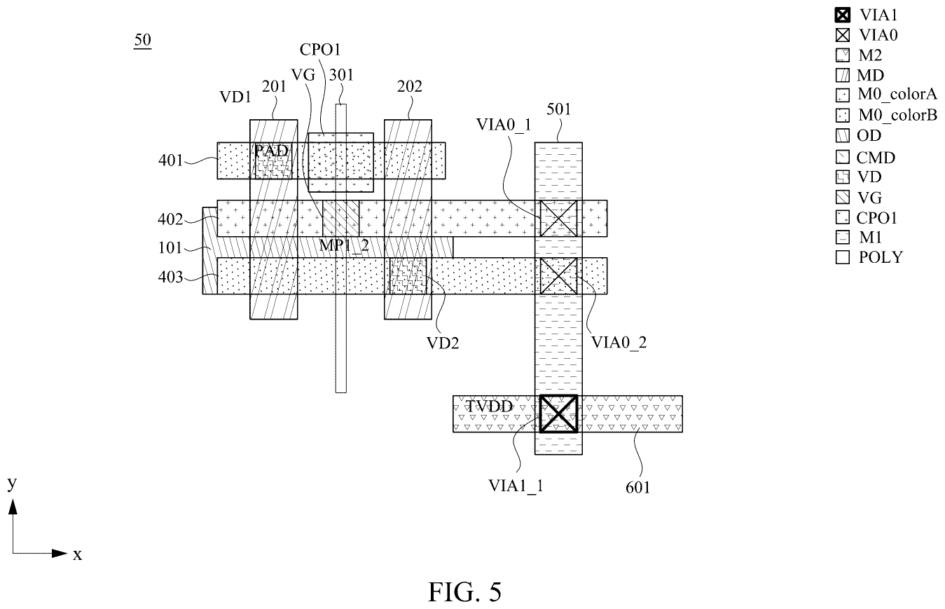

Reference is now made to FIG. 5. FIG. 5 is a schematic diagram in a layout view of part of an integrated circuit 50, in accordance with some embodiments. The integrated circuit 50 is configured with respect to, for example, the integrated circuit 30 of FIG. 3.

Compared with FIG. 3, instead of the conductive lines 402-403 coupled to separated conductive lines, the conductive lines 402-403 of the integrated circuit 50 in FIG. 5 are coupled to the conductive rail 501 and further to the conductive trace 601 through the via VIA1_1.

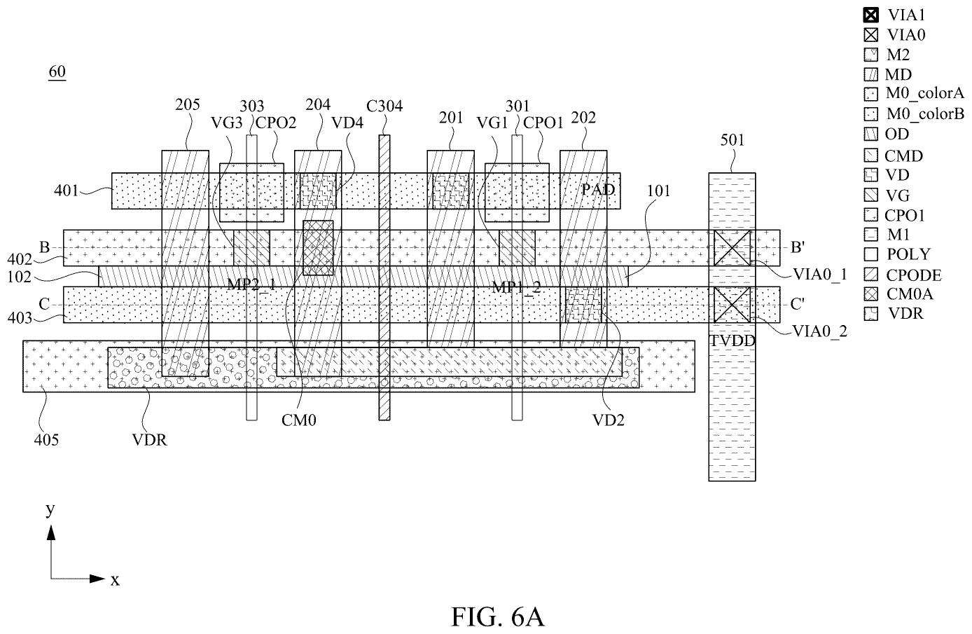

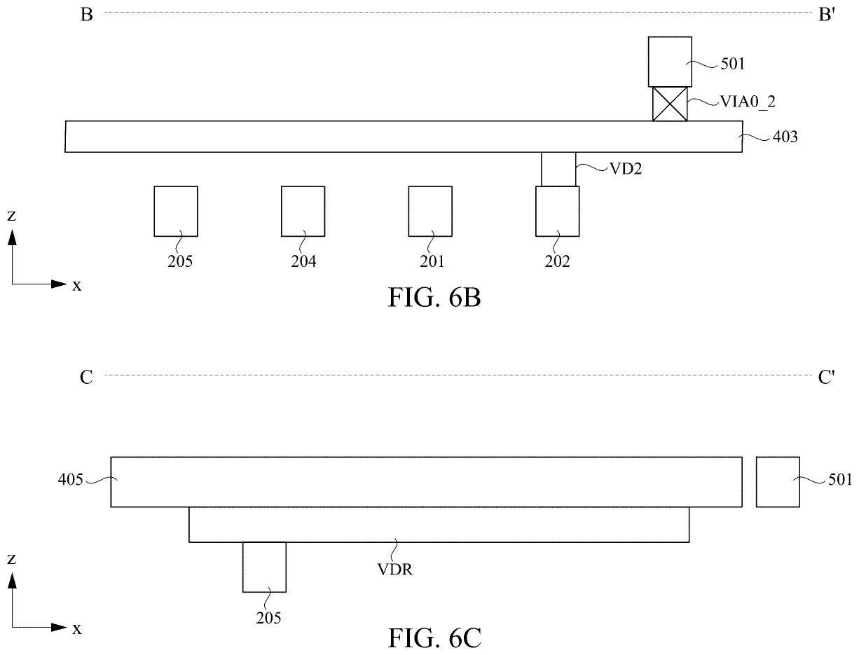

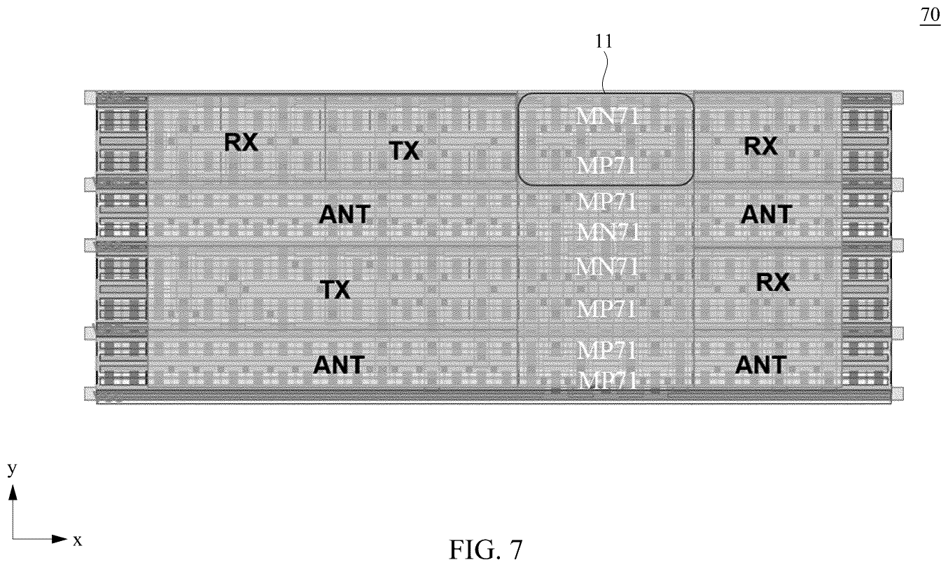

Reference is now made to FIG. 6A. FIG. 6A is a schematic diagram in a layout view of part of an integrated circuit 60, in accordance with some embodiments. With respect to the embodiments of FIGS. 1-5, like elements in FIG. 6A are designated with the same reference numbers for ease of understanding. In some embodiments, the integrated circuit 60 is configured with respect to, for example, the I/O circuit IOC of FIG. 2 and the integrated circuit 50 of FIG. 5.

As shown in FIG. 6A, the integrated circuit 60 further includes a P-type transistor MP2_1. In some embodiments, the transistor MP2_1 is configured with respect to, for example, the transistor MP2 of the receiver/transmitter circuit 13 in FIG. 2.

Specifically, the integrated circuit 60 further includes an active area 102, conductive segments 204-205, a gate structure 303, and conductive lines 404-405. In some embodiments, the active area 102 is configured with respect to, for example, the active area 101. The gate structure 303 is configured with respect to, for example, the gate structure 301. The conductive lines 404 and 405 are configured with respect to, for example, the conductive line 401.

The active areas 101 and 102 are separated from each other by a continuous polysilicon line over active region edge (CPODE) C304 along x direction. In some embodiments, the CPODE may be formed using a shallow trench isolation (“STI”) technique. The trench may be deposited with a dielectric material. By virtue of using a dielectric material, the CPODE does not provide an electrical or conductive path, and may prevent or at least reduce/minimize current leakage across the active areas 101 and 102.

The conductive segments 204-205 and the gate structure 303 cross the active area 102. The conductive segments 201 and 204 are disposed between the conductive segments 202 and 205. In some embodiments, the conductive segment 204 corresponds to the drain/source terminal of the transistor MP2_1 and is coupled to the pad 10 through coupled to the conductive line 401. The conductive segment 205 corresponds to the source/drain terminal of the transistor MP2_1 and is coupled to the conductive line 405 through a conductive structure VDR that extends in x direction and overlaps with the conductive line 405. The conductive line 405 is further coupled to the voltage terminal n3 to receive the supply voltage VDD.

In some embodiments, a CMD layer (i.e., dummy source/drain electrodes) covers the conductive segment 204 to isolate the conductive segment 204 from the conductive structure VDR and the conductive line 405. Alternatively stated, as shown in FIG. 6A, the conductive segments 201, 202, and 204 are disconnected from the voltage terminal n3 that provides the supply voltage VDD.

The conductive line 404 is electrically isolated from the conductive line 402 by a CM0A layer (i.e., dummy metal contact.) Alternatively stated, the conductive lines 402 and 404 are separated from each other along x direction.

The gate structure 303 corresponds to the gate terminal of the transistor MP2_1 and is coupled to internal signal to the functional circuit FC of FIG. 2 through a via VG3 and the conductive line 404.

Reference is now made to FIG. 6B. FIG. 6B depicts a cross-section diagram of the integrated circuit 60 of FIG. 6A, along line BB′, in accordance with some embodiments.

For illustration, the conductive segments 201, and 204-205 are separated from the conductive line 403 along z direction and electrically isolated from the conductive rail 501. The conductive segment 202 is coupled to the conductive line 403 through the via VD2 and further to the conductive rail 501 through the via VIA0_2.

Reference is now made to FIG. 6C. FIG. 6C depicts a cross-section diagram of the integrated circuit 60 of FIG. 6A, along line CC′, in accordance with some embodiments.

For illustration, the conductive segment 205 is coupled to the conductive line 405 through the conductive structure VDR interposed between the conductive line 405 and the conductive segment 205. The conductive line 405 is separated from the conductive rail 501 along x direction.

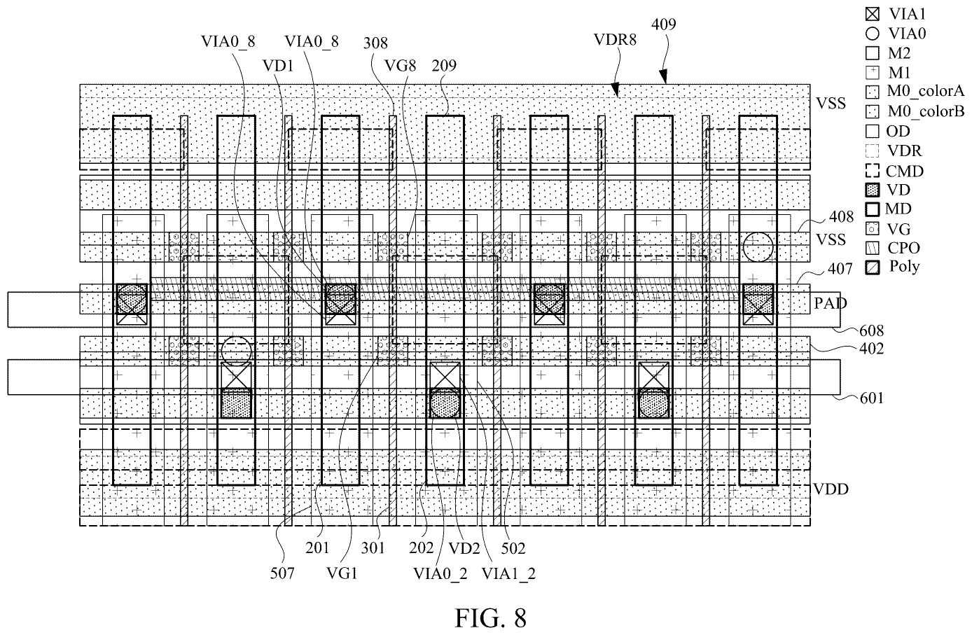

Reference is now made to FIG. 7. FIG. 7 is a schematic diagram in a layout view of part of an integrated circuit 70, in accordance with some embodiments. With respect to the embodiments of FIGS. 1-6C, like elements in FIG. 7 are designated with the same reference numbers for ease of understanding. In some embodiments, the integrated circuit 70 is configured with respect to, for example, the I/O circuit IOC of FIG. 2 and the integrated circuit 50 of FIG. 5.

As illustratively shown in FIG. 7, the ESD protection circuit 11 is arranged between layout patterns corresponding to the receiver RX, the transmitter TX, the antenna effect protection circuit ANT. In some embodiments, the ESD protection circuit 11 includes multiple P-type transistors MP71 for implementing the transistor MP1 of FIG. 2 and multiple N-type transistors MN71 for implementing the transistor MN1 of FIG. 2.

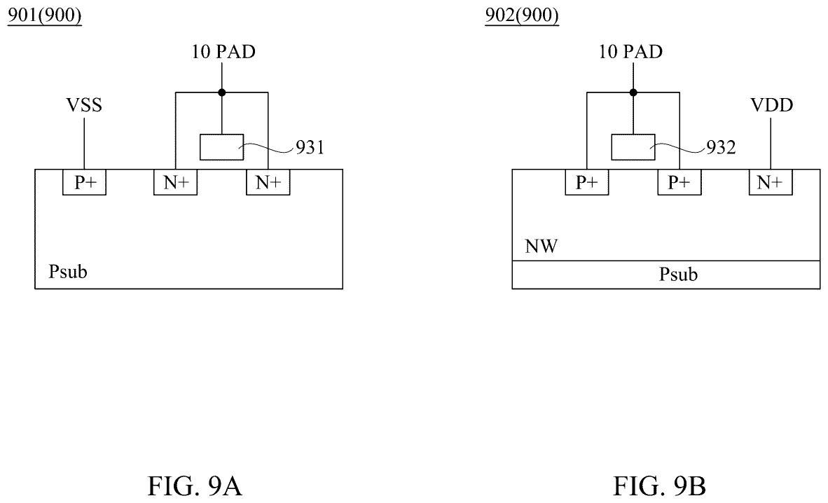

Reference is now made to FIG. 8. FIG. 8 is a schematic diagram in a layout view of part of the integrated circuit 70 of FIG. 7, in accordance with some embodiments. With respect to the embodiments of FIGS. 1-7, like elements in FIG. 8 are designated with the same reference numbers for ease of understanding.

As shown in FIG. 8, the conductive segment 202, corresponding to the drain/source terminal of the transistor MP71, is shared by the transistor MN71 and corresponds to the drain/source terminal of the transistor MN71. The conductive segment 202 is further coupled to the pad 10 through the via VD1 coupled to a conductive line 407, a via VIA0_8 coupling the conductive line 407 to a conductive rail 507, and a via VIA1_8 coupling the conductive rail 507 to a conductive trace 608. The conductive trace 608 is coupled to the pad 10.

Furthermore, a conductive segment 209 extends in y direction and corresponds to a source/drain terminal of the transistor MN71. The conductive segment 209 is further coupled to a conductive line 409 through a conductive structure VDR8. In some embodiments, the conductive line 409 is coupled to the supply voltage VSS provided by the voltage terminal n2.

A gate structure 308 extends in y direction and corresponds to a gate terminal of the transistor MN71. The gate structure 308 is coupled to a conductive line 408 that is coupled to the supply voltage VSS provided by the voltage terminal n2.

In some embodiments, the conductive segment 209 is configured with respect to, for example, the conductive segment 201. The gate structure 308 is configured with respect to, for example, the gate structure 301. The conductive lines 407 to 409 are configured with respect to, for example, the conductive line 401. The conductive rail 507 is configured with respect to, for example, the conductive rail 501. The conductive trace 608 is configured with respect to, for example, the conductive trace 601. The conductive structure VDR8 is configured with respect to, for example, the conductive structure VDR.

Reference is now made to FIGS. 9A to 9B. FIGA. 9A and 9B are schematic diagrams of parts of an antenna effect protection circuit 900, in accordance with some embodiments. In some embodiments, the antenna effect protection circuit 900 is configured with respect to, for example, the antenna effect protection circuit ANT in FIG. 1 and FIG. 7.

In some embodiments, the antenna effect protection circuit 900 includes at least one transistor 901 of a first type, e.g., an N-type, as shown in FIG. 9A and at least one transistor 902 of a second type, e.g., the P-type, as shown in FIG. 9B. The gate, source and drain of each of the transistors are electrically coupled together to the pad 10.

As a result, the transistors are electrically coupled as dummy transistors and do not affect operation or functionality of the IC device after the manufacturing process. The P-type and N-type transistors 901-902 of the antenna effect protection circuit 900 form, together with a substrate Psub of an IC device, corresponding diode structures that protect other, functional transistors from being damaged due to the antenna effect during the manufacturing process of the IC device.

As illustrated in FIG. 9A, N-type dopants are added to the substrate Psub to correspondingly form N-doped regions N+corresponding to N-type transistor 901. The N-doped regions N+are coupled to a gate region 931 of the N-type transistor 901 and the pad 10. In addition, a P-doped region P+is formed in the substrate Psub and coupled to the voltage terminal n2 to receive the supply voltage VSS.

In FIG. 9A, P-type dopants are added to an N-type well NW in the substrate Psub to correspondingly form P-doped regions P+ corresponding to P-type transistor 902. The P-doped regions P+ are coupled to a gate region 932 of the P-type transistor 902 and the pad 10. In addition, an N-doped region N+ is formed in the N-type well NW and coupled to the voltage terminal n3 to receive the supply voltage VDD.

The configurations of FIGS. 1 to 9B are given for illustrative purposes. Various implements are within the contemplated scope of the present disclosure.

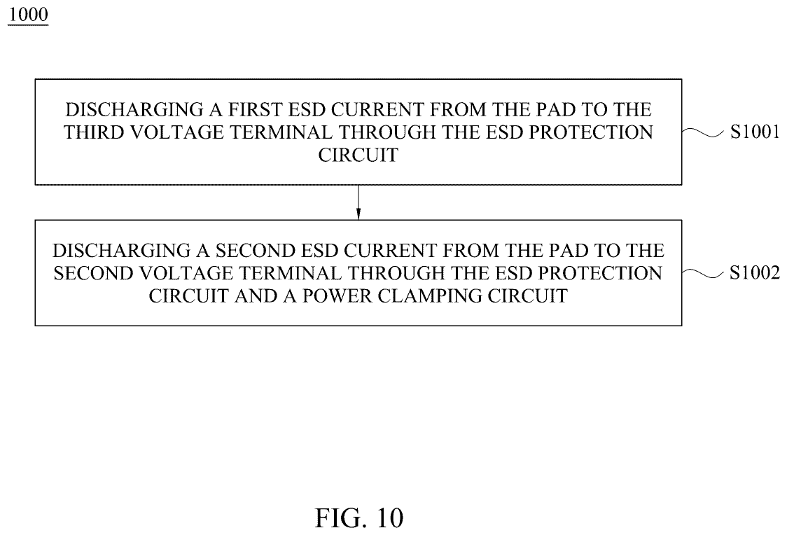

FIG. 10 is a flow chart of a method 1000 of manufacturing an integrated circuit, in accordance with some embodiments. It is understood that additional operations can be provided before, during, and after the processes shown by FIG. 10, and some of the operations described below can be replaced or eliminated, for additional embodiments of the method. The order of the operations/processes may be interchangeable. Throughout the various views and illustrative embodiments, like reference numbers are used to designate like elements. The method 1000 has operations S1001-S1002 and will be discussed with reference to embodiments of FIG. 2 to FIG. 3.

In operation S1001, the ESD current I_PD is discharged from the pad 10 to the voltage terminal n1 through the ESD protection circuit 11. In some embodiments, the P-type transistor MP1 is conducted to transmit the ESD current I_PD.

In operation S1002, the ESD current I_PS is discharged from the pad 10 to the voltage terminal n2 through the ESD protection circuit 11 and the power clamp circuit 16.

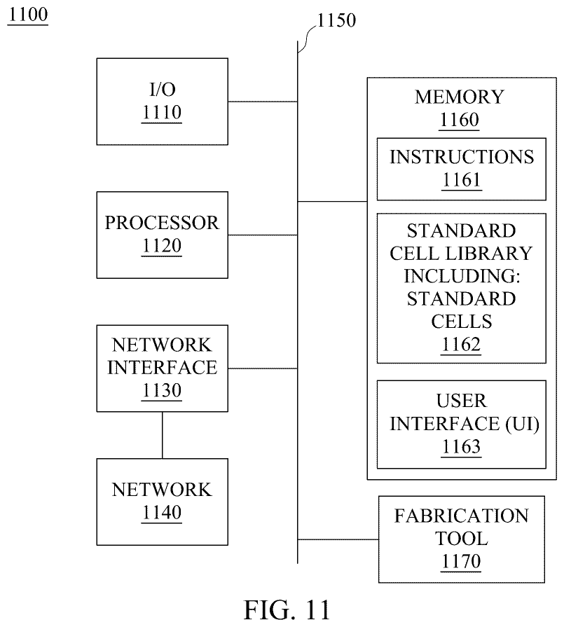

Reference is now made to FIG. 11. FIG. 11 is a block diagram of an electronic design automation (EDA) system 1100 for designing the integrated circuit layout design, in accordance with some embodiments of the present disclosure. EDA system 1100 is configured to implement one or more operations for manufacturing the IC device 100, the integrated circuits 30, 40, 50, 60 and 70, and further explained in conjunction with FIGS. 1A-10. In some embodiments, EDA system 1100 includes an APR system.

In some embodiments, EDA system 1100 is a general purpose computing device including a hardware processor 1120 and a non-transitory, computer-readable storage medium 1160. Storage medium 1160, amongst other things, is encoded with, i.e., stores, computer program code (instructions) 1161, i.e., a set of executable instructions. Execution of instructions 1161 by hardware processor 1120 represents (at least in part) an EDA tool which implements a portion or all of, e.g., manufacturing the integrated circuits 30, 40, 50, 60 and 70.

The processor 1120 is electrically coupled to computer-readable storage medium 1160 via a bus 1150. The processor 1120 is also electrically coupled to an I/O interface 1110 and a fabrication tool 1170 by bus 1150. A network interface 1130 is also electrically connected to processor 1120 via bus 1150. Network interface 1130 is connected to a network 1140, so that processor 1120 and computer-readable storage medium 1160 are capable of connecting to external elements via network 1140. The processor 1120 is configured to execute computer program code 1161 encoded in computer-readable storage medium 1160 in order to cause EDA system 1100 to be usable for performing a portion or all of the noted processes and/or methods. In one or more embodiments, processor 1120 is a central processing unit (CPU), a multi-processor, a distributed processing system, an application specific integrated circuit (ASIC), and/or a suitable processing unit.

In one or more embodiments, computer-readable storage medium 1160 is an electronic, magnetic, optical, electromagnetic, infrared, and/or a semiconductor system (or apparatus or device). For example, computer-readable storage medium 1160 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1160 includes a compact disk-read only memory (CD-ROM), a compact disk-read/write (CD-R/W), and/or a digital video disc (DVD).

In one or more embodiments, storage medium 1160 stores computer program code 1161 configured to cause EDA system 1100 (where such execution represents (at least in part) the EDA tool) to be usable for performing a portion or all of the noted processes and/or methods. In one or more embodiments, storage medium 1160 also stores information which facilitates performing a portion or all of the noted processes and/or methods. In one or more embodiments, storage medium 1160 stores library 1162 of standard cells including such standard cells as disclosed herein, for example, a cell including portions in the integrated circuits 30, 40, 50, 60 and 70.

EDA system 1100 includes I/O interface 1110. I/O interface 1110 is coupled to external circuitry. In one or more embodiments, I/O interface 1110 includes a keyboard, keypad, mouse, trackball, trackpad, touchscreen, and/or cursor direction keys for communicating information and commands to processor 1120.

EDA system 1100 also includes network interface 1130 coupled to processor 1120. Network interface 1130 allows EDA system 1100 to communicate with network 1140, to which one or more other computer systems are connected. Network interface 1130 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1100.

EDA system 1100 also includes the fabrication tool 1170 coupled to processor 1120. The fabrication tool 1170 is configured to fabricate integrated circuits, e.g., the integrated circuits 30, 40, 50, 60 and 70, according to the design files processed by the processor 1120.

EDA system 1100 is configured to receive information through I/O interface 1110. The information received through I/O interface 1110 includes one or more of instructions, data, design rules, libraries of standard cells, and/or other parameters for processing by processor 1120. The information is transferred to processor 1120 via bus 1150. EDA system 1100 is configured to receive information related to a UI through I/O interface 1110. The information is stored in computer-readable medium 1160 as user interface (UI) 1163.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, for example, one or more of an optical disk, such as a DVD, a magnetic disk, such as a hard disk, a semiconductor memory, such as a ROM, a RAM, a memory card, and the like.

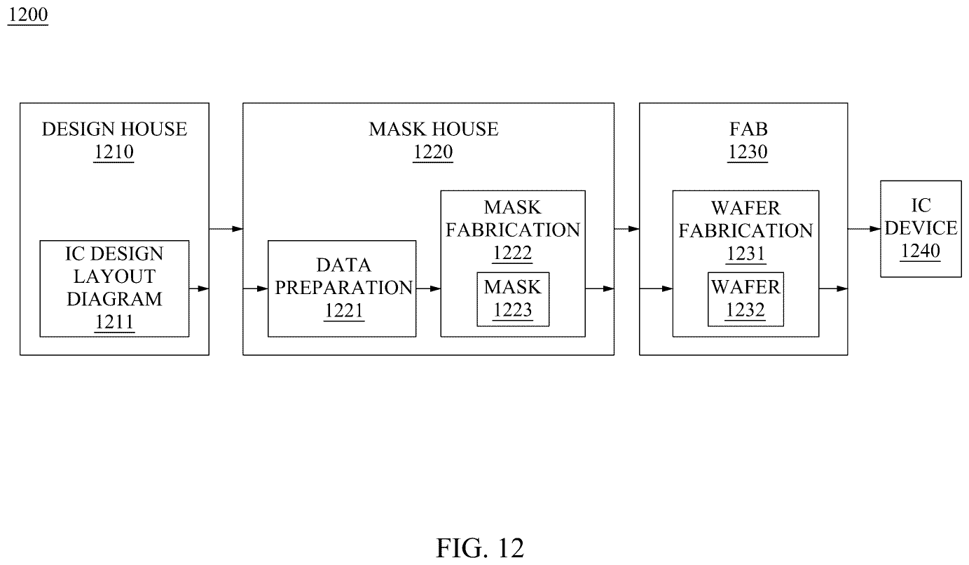

FIG. 12 is a block diagram of IC manufacturing system 1200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using IC manufacturing system 1200.

In FIG. 12, IC manufacturing system 1200 includes entities, such as a design house 1210, a mask house 1220, and an IC manufacturer/fabricator (“fab”) 1230, that interact with one another in the design, development, and manufacturing cycles and/or services related to manufacturing an IC device 1240. The entities in IC manufacturing system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1210, mask house 1220, and IC fab 1230 is owned by a single larger company. In some embodiments, two or more of design house 1210, mask house 1220, and IC fab 1230 coexist in a common facility and use common resources.

Design house (or design team) 1210 generates an IC design layout diagram 1211. IC design layout diagram 1211 includes various geometrical patterns, for example, an IC layout design depicted in FIGS. 3-8, designed for an IC device 1240, for example, integrated circuits 30, 40, 50, 60 and 70, discussed above with respect to FIGS. 3-9B. The geometrical patterns correspond to patterns of metal, oxide, or semiconductor layers that make up the various components of IC device 1240 to be fabricated. The various layers combine to form various IC features. For example, a portion of IC design layout diagram 1211 includes various IC features, such as an active region, gate electrode, source and drain, conductive segments or vias of an interlayer interconnection, to be formed in a semiconductor substrate (such as a silicon wafer) and various material layers disposed on the semiconductor substrate. Design house 1210 implements a proper design procedure to form IC design layout diagram 1211. The design procedure includes one or more of logic design, physical design or place and route. IC design layout diagram 1211 is presented in one or more data files having information of the geometrical patterns. For example, IC design layout diagram 1211 can be expressed in a GDSII file format or DFII file format.

Mask house 1220 includes data preparation 1221 and mask fabrication 1222. Mask house 1220 uses IC design layout diagram 1211 to manufacture one or more masks 1223 to be used for fabricating the various layers of IC device 1240 according to IC design layout diagram 1211. Mask house 1220 performs mask data preparation 1221, where IC design layout diagram 1211 is translated into a representative data file (“RDF”). Mask data preparation 1221 provides the RDF to mask fabrication 1222. Mask fabrication 1222 includes a mask writer. A mask writer converts the RDF to an image on a substrate, such as a mask (reticle) 1223 or a semiconductor wafer 1233. The IC design layout diagram 1211 is manipulated by mask data preparation 1221 to comply with particular characteristics of the mask writer and/or requirements of IC fab 1230. In FIG. 12, data preparation 1221 and mask fabrication 1222 are illustrated as separate elements. In some embodiments, data preparation 1221 and mask fabrication 1222 can be collectively referred to as mask data preparation.

In some embodiments, data preparation 1221 includes optical proximity correction (OPC) which uses lithography enhancement techniques to compensate for image errors, such as those that can arise from diffraction, interference, other process effects and the like. OPC adjusts IC design layout diagram 1211. In some embodiments, data preparation 1221 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, data preparation 1221 includes a mask rule checker (MRC) that checks the IC design layout diagram 1211 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1211 to compensate for limitations during mask fabrication 1222, which may undo part of the modifications performed by OPC in order to meet mask creation rules.

In some embodiments, data preparation 1221 includes lithography process checking (LPC) that simulates processing that will be implemented by IC fab 1230 to fabricate IC device 1240. LPC simulates this processing based on IC design layout diagram 1211 to create a simulated manufactured device, such as IC device 1240. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1211.

It should be understood that the above description of data preparation 1221 has been simplified for the purposes of clarity. In some embodiments, data preparation 1221 includes additional features such as a logic operation (LOP) to modify the IC design layout diagram 1211 according to manufacturing rules. Additionally, the processes applied to IC design layout diagram 1211 during data preparation 1221 may be executed in a variety of different orders.

After data preparation 1221 and during mask fabrication 1222, a mask 1223 or a group of masks 1223 are fabricated based on the modified IC design layout diagram 1211. In some embodiments, mask fabrication 1222 includes performing one or more lithographic exposures based on IC design layout diagram 1211. In some embodiments, an electron-beam (e-beam) or a mechanism of multiple e-beams is used to form a pattern on a mask (photomask or reticle) 1223 based on the modified IC design layout diagram 1211. Mask 1223 can be formed in various technologies. In some embodiments, mask 1223 is formed using binary technology. In some embodiments, a mask pattern includes opaque regions and transparent regions. A radiation beam, such as an ultraviolet (UV) beam, used to expose the image sensitive material layer (for example, photoresist) which has been coated on a wafer, is blocked by the opaque region and transmits through the transparent regions. In one example, a binary mask version of mask 1223 includes a transparent substrate (for example, fused quartz) and an opaque material (for example, chromium) coated in the opaque regions of the binary mask. In another example, mask 1223 is formed using a phase shift technology. In a phase shift mask (PSM) version of mask 1223, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1222 is used in a variety of processes. For example, such a mask(s) is used in an ion implantation process to form various active areas in semiconductor wafer 1233, in an etching process to form various etching regions in semiconductor wafer 1233, and/or in other suitable processes.

IC fab 1230 includes wafer fabrication 1232. IC fab 1230 is an IC fabrication business that includes one or more manufacturing facilities for the fabrication of a variety of different IC products. In some embodiments, IC Fab 1230 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1230 uses mask(s) 1223 fabricated by mask house 1220 to fabricate IC device 1240. Thus, IC fab 1230 at least indirectly uses IC design layout diagram 1211 to fabricate IC device 1240. In some embodiments, semiconductor wafer 1233 is fabricated by IC fab 1230 using mask(s) 1223 to form IC device 1240. In some embodiments, the IC fabrication includes performing one or more lithographic exposures based at least indirectly on IC design layout diagram 1211. Semiconductor wafer 1233 includes a silicon substrate or other proper substrate having material layers formed thereon. Semiconductor wafer 1233 further includes one or more of various active areas, dielectric features, multilevel interconnects, and the like (formed at subsequent manufacturing steps).

An integrated circuit is provided and includes a header circuit coupled to a first voltage terminal providing a first supply voltage and configured to provide a second supply voltage at a second voltage terminal; a receiver/transmitter circuit coupled between the second voltage terminal and a third voltage terminal providing a third supply voltage smaller than the second supply voltage; and an electrostatic discharge (ESD) protection circuit coupled to a pad and the receiver/transmitter circuit, and further coupled between the first voltage terminal and the third voltage terminal.

In some embodiments, the ESD protection circuit includes: a first transistor having: a gate terminal and a source/drain terminal that are coupled to the first voltage terminal; and a second transistor having: a gate terminal and a source/drain terminal that are coupled to the third voltage terminal; and a drain/source terminal coupled to a drain/source terminal of the first transistor, the pad, and the receiver/transmitter circuit.

In some embodiments, wherein the receiver/transmitter circuit includes: a third transistor having: a source/drain terminal coupled to the second voltage terminal; a drain/source terminal coupled to the pad; and a body terminal of the third transistor is coupled to the first voltage terminal; and a fourth transistor having: a gate terminal coupled to a gate terminal of the third transistor; a source/drain terminal coupled to the third voltage terminal; and a drain/source terminal coupled to the pad.

In some embodiments, the first transistor and the third transistor are of a first conductivity type, and the second transistor and the fourth transistor are of a second conductivity type different from the first conductivity type.

In some embodiments, the first transistor and the third transistor are P-type transistor, and the second transistor and the fourth transistor are N-type transistor.

In some embodiments, the ESD protection circuit is configured to discharge an ESD current flowing from the pad to the first voltage terminal. The integrated circuit further includes: a power clamp circuit coupled between the first voltage terminal and the third voltage terminal, and configured to discharge the ESD current from the first voltage terminal to the third voltage terminal.

In some embodiments, the receiver/transmitter circuit includes: a first transistor having: a source/drain terminal coupled to the second voltage terminal; and a drain/source terminal coupled to the pad. The ESD protection circuit includes: a second transistor having a gate terminal and a source/drain terminal that are coupled to a body terminal of the first transistor.

In some embodiments, the ESD protection circuit is configured to discharge an ESD current from the pad to the first voltage terminal.

In some embodiments, the integrated circuit further includes: a capacitor coupled to the header circuit and the receiver/transmitter circuit and disconnected from the second transistor.

In some embodiments, the first supply voltage is greater than the second supply voltage.

An integrated circuit is provided and includes a receiver/transmitter circuit coupled between a first voltage terminal and a second voltage terminal, and including a first transistor having a first terminal coupled to the first voltage terminal and a second terminal coupled to a pad; and an electrostatic discharge (ESD) protection circuit including a second transistor that is coupled to the receiver/transmitter circuit at the pad and further coupled to a third voltage terminal different from the second voltage terminal. The first transistor and the second transistor are of a same conductivity type.

In some embodiments, the first transistor and the second transistor are P-type transistors.

In some embodiments, the integrated circuit further includes a first conductive line and a second conductive line extending in a first direction, wherein the first conductive line is coupled to the pad, and the second conductive line is coupled to the second voltage terminal. The first transistor includes a first conductive segment and a second conductive segment extending in a second direction. The first conductive segment is coupled to the first conductive line, and the second conductive segment is coupled to the second conductive line through a conductive structure that overlaps with the second conductive line. The second transistor includes a third conductive segment and a fourth conductive segment extending in the second direction. The third conductive segment is coupled to the first conductive line, and the fourth conductive segment is coupled to the third voltage terminal.

In some embodiments, the integrated circuit further includes a third conductive line extending in the first direction and coupling to the fourth conductive segment, wherein the first conductive line to the third conductive line are separated from each other along the second direction; and a conductive rail coupled to the third voltage terminal and the third conductive line. The conductive rail is arranged in a layer above where the third conductive line is arranged in.

In some embodiments, the ESD protection circuit is configured to discharge an ESD current from the pad to the third voltage terminal through the conductive rail.

In some embodiments, the first conductive segment and the third conductive segment are disposed between the second conductive segment and the fourth conductive segment.

In some embodiments, a voltage level at the first voltage terminal is equal to a voltage level at the third voltage terminal.

A method of discharging electrostatic discharge (ESD) currents in an integrated circuit, wherein the integrated circuit includes a receiver/transmitter circuit and an ESD protection circuit that are coupled to a pad, wherein the receiver/transmitter circuit is coupled between a first voltage terminal and a second voltage terminal, and the ESD protection circuit is coupled between the second voltage terminal and a third voltage terminal different from the first voltage terminal and the second voltage terminal. The method includes operations of: discharging a first ESD current from the pad to the third voltage terminal through the ESD protection circuit; and discharging a second ESD current from the pad to the second voltage terminal through the ESD protection circuit and a power clamp circuit.

In some embodiments, the power clamping circuit is electrically connected between the second voltage terminal and the third voltage terminal.

In some embodiments, discharging the second ESD current further includes: conducting a P-type transistor that has a gate terminal and source terminal coupled together to the third voltage terminal and a drain terminal coupled to the pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a header circuit coupled to a first voltage terminal providing a first supply voltage and configured to provide a second supply voltage at a second voltage terminal;
a receiver/transmitter circuit coupled between the second voltage terminal and a third voltage terminal providing a third supply voltage smaller than the second supply voltage; and
an electrostatic discharge (ESD) protection circuit coupled to a pad and the receiver/transmitter circuit, and further coupled between the first voltage terminal and the third voltage terminal.

2. The integrated circuit of claim 1, wherein the ESD protection circuit comprises:
a first transistor having:
a gate terminal and a source/drain terminal that are coupled to the first voltage terminal; and
a second transistor having:
a gate terminal and a source/drain terminal that are coupled to the third voltage terminal; and
a drain/source terminal coupled to a drain/source terminal of the first transistor, the pad, and the receiver/transmitter circuit.

3. The integrated circuit of claim 2, wherein the receiver/transmitter circuit comprises:
a third transistor having:
a source/drain terminal coupled to the second voltage terminal;
a drain/source terminal coupled to the pad; and
a body terminal of the third transistor is coupled to the first voltage terminal; and
a fourth transistor having:
a gate terminal coupled to a gate terminal of the third transistor;
a source/drain terminal coupled to the third voltage terminal; and
a drain/source terminal coupled to the pad.

4. The integrated circuit of claim 3, wherein the first transistor and the third transistor are of a first conductivity type, and the second transistor and the fourth transistor are of a second conductivity type different from the first conductivity type.

5. The integrated circuit of claim 3, wherein the first transistor and the third transistor are P-type transistor, and the second transistor and the fourth transistor are N-type transistor.

6. The integrated circuit of claim 2, wherein the ESD protection circuit is configured to discharge an ESD current flowing from the pad to the first voltage terminal,
wherein the integrated circuit further comprises:
a power clamp circuit coupled between the first voltage terminal and the third voltage terminal, and configured to discharge the ESD current from the first voltage terminal to the third voltage terminal.

7. The integrated circuit of claim 1, wherein the receiver/transmitter circuit comprises:
a first transistor having:
a source/drain terminal coupled to the second voltage terminal; and
a drain/source terminal coupled to the pad;
wherein the ESD protection circuit comprises:
a second transistor having a gate terminal and a source/drain terminal that are coupled to a body terminal of the first transistor.

8. The integrated circuit of claim 7, wherein the ESD protection circuit is configured to discharge an ESD current from the pad to the first voltage terminal.

9. The integrated circuit of claim 7, further comprising:
a capacitor coupled to the header circuit and the receiver/transmitter circuit and disconnected from the second transistor.

10. The integrated circuit of claim 1, wherein the first supply voltage is greater than the second supply voltage.

11. An integrated circuit, comprising:
a receiver/transmitter circuit coupled between a first voltage terminal and a second voltage terminal, and comprising a first transistor having a first terminal coupled to the first voltage terminal and a second terminal coupled to a pad; and
an electrostatic discharge (ESD) protection circuit comprising a second transistor that is coupled to the receiver/transmitter circuit at the pad and further coupled to a third voltage terminal different from the second voltage terminal,
wherein the first transistor and the second transistor are of a same conductivity type.

12. The integrated circuit of claim 11, wherein the first transistor and the second transistor are P-type transistors.

13. The integrated circuit of claim 11, further comprising:
a first conductive line and a second conductive line extending in a first direction, wherein the first conductive line is coupled to the pad, and the second conductive line is coupled to the second voltage terminal;
wherein the first transistor comprises:
a first conductive segment and a second conductive segment extending in a second direction,
wherein the first conductive segment is coupled to the first conductive line, and the second conductive segment is coupled to the second conductive line through a conductive structure that overlaps with the second conductive line;
wherein the second transistor comprises:
a third conductive segment and a fourth conductive segment extending in the second direction,
wherein the third conductive segment is coupled to the first conductive line, and the fourth conductive segment is coupled to the third voltage terminal.

14. The integrated circuit of claim 13, further comprising:
a third conductive line extending in the first direction and coupling to the fourth conductive segment, wherein the first conductive line to the third conductive line are separated from each other along the second direction; and
a conductive rail coupled to the third voltage terminal and the third conductive line,
wherein the conductive rail is arranged in a layer above where the third conductive line is arranged in.

15. The integrated circuit of claim 14, wherein the ESD protection circuit is configured to discharge an ESD current from the pad to the third voltage terminal through the conductive rail.

16. The integrated circuit of claim 13, wherein the first conductive segment and the third conductive segment are disposed between the second conductive segment and the fourth conductive segment.

17. The integrated circuit of claim 11, wherein a voltage level at the first voltage terminal is equal to a voltage level at the third voltage terminal.

18. A method of discharging electrostatic discharge (ESD) currents in an integrated circuit, wherein the integrated circuit comprises a receiver/transmitter circuit and an ESD protection circuit that are coupled to a pad, wherein the receiver/transmitter circuit is coupled between a first voltage terminal and a second voltage terminal, and the ESD protection circuit is coupled between the second voltage terminal and a third voltage terminal different from the first voltage terminal and the second voltage terminal,
wherein the method comprises operations of:
discharging a first ESD current from the pad to the third voltage terminal through the ESD protection circuit; and
discharging a second ESD current from the pad to the second voltage terminal through the ESD protection circuit and a power clamp circuit.

19. The method of claim 18, wherein the power clamp circuit is electrically connected between the second voltage terminal and the third voltage terminal.

20. The method of claim 18, wherein discharging the second ESD current further comprises:
conducting a P-type transistor that has a gate terminal and source terminal coupled together to the third voltage terminal and a drain terminal coupled to the pad.
